(19) United States
(12) Patent Application Publication
(10) Pub. No.: US 2017/0352779 A1
(43) Pub. Date: Dec. 7, 2017

(54) NANOPARTICLE PHOSPHOR ELEMENT AND LIGHT EMITTING ELEMENT

(71) Applicant: Sharp Kabushiki Kaisha, Osaka (JP)

(72) Inventors: Yasutaka KUZUMOTO, Sakai City (JP); Tatsuya RYOHWA, Sakai City (JP); Noriyuki YAMAZUMI, Sakai City (JP); Makoto IZUMI, Sakai City (JP)

(21) Appl. No.: 15/591,229

(22) Filed: May 10, 2017

(30) Foreign Application Priority Data
Jun. 7, 2016 (JP) 2016-113518
Mar. 14, 2017 (JP) 2017-048867

(51) Int. Cl. H01L 33/06; C08K 3/30; H01L 33/50; C09K 11/02; C09K 11/88; B82Y 20/00; B82Y 40/00

(52) U.S. Cl. CPC H01L 33/06; C09K 11/025; C08K 3/30; C09K 11/883; H01L 33/502; B82Y 40/00; B82Y 20/00; C08K 2201/001; C08K 2003/3036; Y10S 977/774; Y10S 977/824; Y10S 977/95

(57) ABSTRACT

A nanoparticle phosphor element includes a capsule-shaped material that has a plurality of concave portions in a surface, a medium that is sealed in the capsule-shaped material, and a semiconductor nanoparticle phosphor that is dispersed in the medium, and a light emitting element includes a sealing material, and the nanoparticle phosphor element of the disclosure that is dispersed in the sealing material.

### BACKGROUND

### 1. Field

The present disclosure relates to a nanoparticle phosphor element including a capsule-shaped material, a medium that is sealed in the capsule-shaped material, and a semiconductor nanoparticle phosphor that is dispersed in the medium.

### 2. Description of the Related Art

It is known that a quantum size effect is exhibited if a semiconductor nanoparticle phosphor is reduced in size to approximately an exciton Bohr radius. The quantum size effect exhibits an effect that if a material is reduced in size, an electron therein is not able to move freely, and energy of the electron is only assumed to be a specific value rather than any value. Furthermore, it is also known that an energy state of the electron is changed with the size of the semiconductor nanoparticle phosphor which confines the electron being changed, and a wavelength of light emitted from the semiconductor nanoparticle phosphor becomes a short wavelength as the semiconductor nanoparticle phosphor is reduced in dimension. The semiconductor nanoparticle phosphor exhibiting such a quantum size effect has attracted attention in use as a phosphor, and research thereof has advanced.

Since the semiconductor nanoparticle phosphor has a large specific surface area and a high surface activity, the semiconductor nanoparticle phosphor is less likely to be stabilized chemically and physically. Accordingly, a method for stabilizing a semiconductor nanoparticle phosphor has been proposed.

For example, Japanese Unexamined Patent Application Publication (Translation of PCT Application) No. 2013-505347 discloses a plurality of coated primary particles such that each primary particle is composed of a primary matrix material, includes a group of semiconductor nanoparticles, and is individually provided with a layer of a surface coating material.

In the technology of Japanese Unexamined Patent Application Publication (Translation of PCT Application) No. 2013-505347, since general materials such as polymer and glass are used as a matrix material, there are problems that agglomeration of the semiconductor nanoparticle phosphor occurs in the matrix, and quantum efficiency of the semiconductor nanoparticle phosphor is lowered.

### SUMMARY

It is desirable to provide a nanoparticle phosphor element that exhibits excellent quantum efficiency by dispersing a semiconductor nanoparticle phosphor appropriately in a medium without agglomeration, and a light emitting element using the nanoparticle phosphor element.

A nanoparticle phosphor element according to an aspect of the disclosure includes a capsule-shaped material having a plurality of concave portions in a surface, a medium that is sealed in the capsule-shaped material, and a semiconductor nanoparticle phosphor that is dispersed in the medium.

A light emitting element according to another aspect of the disclosure includes a sealing material and the nanoparticle phosphor element according to the aspect of the disclosure that is dispersed in the sealing material.

### BRIEF DESCRIPTION OF THE DRAWINGS

FIG. 1 is a diagram schematically illustrating a nanoparticle phosphor element and a light emitting element according to Embodiment 1;

FIG. 2 is a diagram schematically illustrating the nanoparticle phosphor element and the light emitting element according to Embodiment 1;

FIG. 3A is a scanning electron microscope photograph of the nanoparticle phosphor element of the disclosure, FIG. 3B is a fluorescence microscopic image photograph of the nanoparticle phosphor element of the disclosure, and FIG. 3C is a scanning electron microscope photograph of a nanoparticle phosphor element of the disclosure;

FIG. 4 is a diagram schematically illustrating a nanoparticle phosphor element according to Embodiment 2; and

FIG. 5 is a diagram schematically illustrating a light emitting element according to Embodiment 3.

### DESCRIPTION OF THE EMBODIMENTS

Hereinafter, the same sign denotes the same portion or an equivalent portion in the drawings of the disclosure. In the drawings, dimensional relationships such as a length, a size and a width are appropriately modified for clarification and simplification of the drawings, and do not denote actual dimensions.

### Embodiment 1

### Nanoparticle Phosphor Element

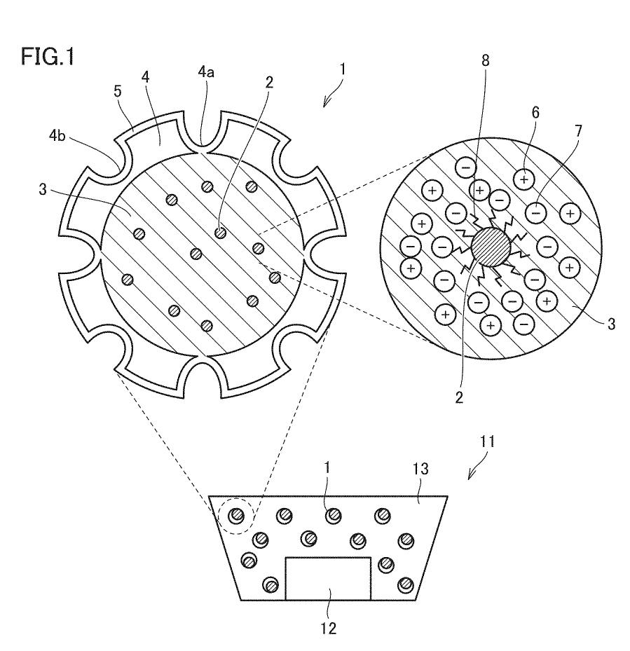

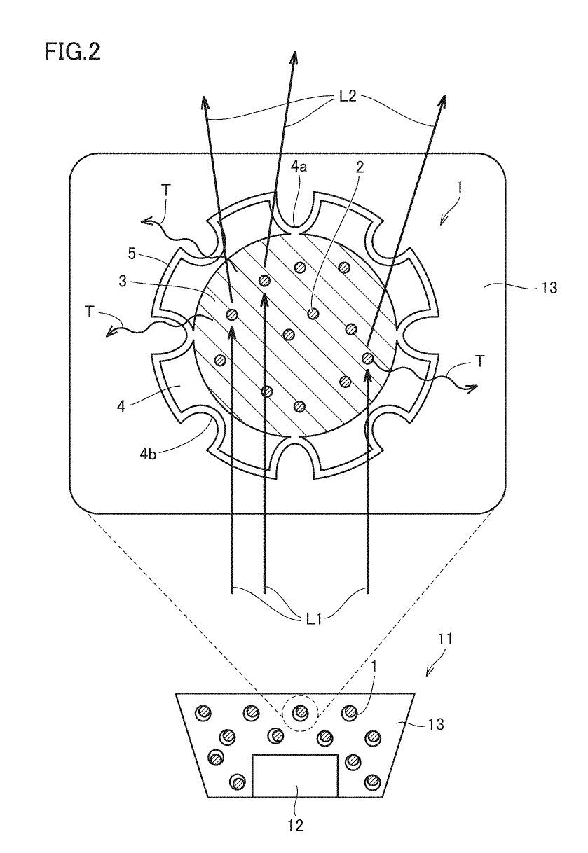

A nanoparticle phosphor element according to Embodiment 1 will be described with reference to FIG. 1 and FIG. 2. FIG. 1 and FIG. 2 are diagrams schematically illustrating a nanoparticle phosphor element 1 and a light emitting element 11 according to Embodiment 1. In FIG. 1, the nanoparticle phosphor element 1 illustrated on an upper left side in the plane of FIG. 1 is illustrated by enlarging a portion of the light emitting element 11 illustrated on a lower side thereof. On an upper right side in the plane of FIG. 1, a semiconductor nanoparticle phosphor 2 and a medium 3 included in the nanoparticle phosphor element 1 are illustrated by being partially enlarged. In FIG. 2, the nanoparticle phosphor element 1 illustrated on an upper side in the plane of FIG. 2 is illustrated by enlarging a portion of the light emitting element 11 illustrated on the lower side thereof.

As illustrated in FIG. 1 and FIG. 2, the nanoparticle phosphor element 1 includes a capsule-shaped material 4 having a plurality of concave portions 4a and 4b in a surface thereof, the medium 3 that is sealed in the capsule-shaped material 4, and the semiconductor nanoparticle phosphor 2 that is dispersed in the medium 3.

### Semiconductor Nanoparticle Phosphor

The semiconductor nanoparticle phosphor 2 is phosphor particles in nano size. A particle size of the semiconductor nanoparticle phosphor may be appropriately selected in accordance with a source material and a desired emission wavelength, and is not particularly limited, but the particle size is preferably in a range of about 1 nm to about 20 nm, and more preferably in a range of about 2 nm to about 5 nm, for example. In a case where the particle size of the semiconductor nanoparticle phosphor is less than about 1 nm, a ratio of a surface area to a volume tends to increase, a surface defect tends to be dominant, and an effect tends to be lowered. In a case where the particle size of the semiconductor nanoparticle phosphor exceeds about 20 nm, a state of dispersion tends to be lowered, and agglomeration and settling tend to occur. Here, in a case where the semiconductor nanoparticle phosphor has a spherical shape, the particle size refers, for example, to an average particle size measured with a particle size distribution analyzer or to a size of the particle observed with an electron microscope. In a case where the semiconductor nanoparticle phosphor has a rod shape, the particle size refers, for example, to lengths of a minor axis and a major axis measured with the electron microscope. In a case where the semiconductor nanoparticle phosphor has a wire shape, the particle size refers, for example, to lengths of a minor axis and a major axis measured with the electron microscope.

The semiconductor nanoparticle phosphor 2 has, for example, a core-shell structure of a nanoparticle core that is composed of a compound semiconductor and a coating layer that is composed of a shell layer coating the nanoparticle core. In an example illustrated in FIG. 1, an organic modifying group 8 is bonded to an outside of the shell layer. It is preferable that the organic modifying group 8 includes a polar functional group.

The nanoparticle core is composed of the compound semiconductor. A composition of the compound semiconductor constituting the nanoparticle core may be, for example, InN, InP, InAs, InSb, InBi, InGaN, InGaP, GaP, AlInN, AlInP, AlGaInN, AlGaInP, CdS, CdSe, CdTe, CdZnS, CdZnSe, CdZnTe, CdZnSSe, CdZnSeTe, In₂S₃, In₂Se₃, Ga₂Se₃, In₂Te₃, Ga₂Te₃, CuInS₂, CuInSe₂, or CuInTe₂. The compound semiconductor of such a composition has bandgap energy that emits visible light of a wavelength of about 380 nm to about 780 nm. Therefore, by controlling the particle size and a mixed crystal ratio thereof, it is possible to form a nanoparticle core which is able to emit desired visible light.

It is preferable that InP, GaP, or CdSe is used as a semiconductor constituting the nanoparticle core. This is because InP, GaP, and CdSe are easily manufactured since InP, GaP, and CdSe are composed of a small number of materials, are materials which exhibit high quantum yields, and exhibit high light emission efficiency when irradiated with LED light. Here, the quantum yield is referred to as a ratio of the number of photons emitting light as fluorescence to the number of photons absorbed.

The shell layer is composed of the compound semiconductor formed by succeeding a crystal structure of the nanoparticle core. The shell layer is a layer formed by growing a semiconductor crystal on the surface of the nanoparticle core, and the nanoparticle core and the shell layer are bonded by a chemical bond. It is preferable that the shell layer is at least one selected from the group consisting of GaAs, GaP, GaN, GaSb, InAs, InP, InN, InSb, AlAs, AlP, AlSb, AlN, ZnO, ZnS, ZnSe, ZnTe, CdS, CdSe, CdTe, CdZnS, CdZnSe, CdZnTe, CdZnSSe, CdZnSeTe, In₂O₃, Ga₂O₃, In₂S_{3,} Ga₂S₃, and ZrO₂, for example. It is preferable that the shell layer has a thickness of about 0.1 nm to about 10 nm. Furthermore, the shell layer may have a multilayer structure which is composed of a plurality of shell layers.

An external surface of the shell layer is bonded to the organic modifying group 8. The organic modifying group 8 is formed by causing a modifying organic compound to react to bond to the external surface of the shell layer. Accordingly, a dangling bond of the surface of the shell layer is capped by the organic modifying group 8 and the surface defect of the shell layer is suppressed, and therefore the nanoparticle core is improved in light emission efficiency.

By using the semiconductor nanoparticle phosphor 2 having the organic modifying group 8 on the surface in this manner, it is possible to suppress agglomeration of the semiconductor nanoparticle phosphors 2. Therefore, the semiconductor nanoparticle phosphor 2 is easily dispersed in the medium 3.

It is preferable that the modifying organic compound has a polar functional group at a terminal thereof. If the modifying organic compound is caused to react with the external surface of the shell layer, the polar functional group is disposed on the surface of the semiconductor nanoparticle phosphor 2. Accordingly, since the surface of the semiconductor nanoparticle phosphor 2 has a polarity, the semiconductor nanoparticle phosphor 2 is dispersed appropriately in the matrix including a constitutional unit derived from an ionic liquid.

Examples of the polar functional group include a carboxyl group, a hydroxyl group, a thiol group, a cyano group, a nitro group, an ammonium group, an imidazolium group, a sulfonium group, a pyridinium group, a pyrrolidinium group, a phosphonium group, and the like.

It is preferable that the polar functional group in the modifying organic compound is an ionic functional group. Since the ionic functional group is high in polarity, the semiconductor nanoparticle phosphor having the ionic functional group on the surface is excellent in dispersibility in the medium in a case where the medium is the ionic liquid or a resin including a constitutional unit derived from the ionic liquid. In a case where the semiconductor nanoparticle phosphor is sealed in the medium which is the ionic liquid or the resin including a constitutional unit derived from the ionic liquid, stability of the semiconductor nanoparticle phosphor is greatly enhanced due to an electrostatic effect by a positive charge and a negative charge of the ionic liquid. The ionic liquid will be described later.

Examples of the ionic functional group include an ammonium group, an imidazolium group, a sulfonium group, a pyridinium group, a pyrrolidinium group, a phosphonium group, and the like.

The other structure of the modifying organic compound is not particularly limited as long as the modifying organic compound has the polar functional group at the terminal thereof. Specifically, dimethylaminoethanethiol (DAET), carboxydecanethiol (CDT), hexadecanethiol (HDT), n-trimethoxysilyl butanoic acid (TMSBA), 3-aminopropyldimethylethoxysilane (APDMES), 3-aminopropyltrimethoxysilane (APTMS), N-trimethoxysilylpropyl-N,N,N-trimethylammonium chloride (TMSP-TMA), 3-(2-aminoethylamino)propyltrimethoxysilane (AEAPTMS), 2-cyanoethyltriethoxysilane, or the like may be used.

A single type thereof, or two or more types thereof in combination may be used as a semiconductor nanoparticle phosphor.

### Medium

The medium 3 may be a liquid or a solid. In a case where the medium 3 is the liquid, examples of the medium include an ionic liquid, octadecene (ODE), isobutyl alcohol, toluene, xylene, ethylene glycol monoethyl ether, and the like. In a case where the medium 3 is the solid, examples of the medium include a resin that includes a constitutional unit derived from an ionic liquid having a polymerizable functional group, epoxy, silicone, (meth)acrylate, silica glass, polystyrene, polypyrrole, polyimide, polyimidazole, polysulfone, polythiophene, polyphosphate, poly(meth)acrylate, polyacrylamide, polypeptide, polysaccharide, and the like. Among these, it is preferable that the medium 3 is the ionic liquid in a case where the medium 3 is a liquid, and the medium 3 is the resin that includes the constitutional unit derived from the ionic liquid having the polymerizable functional group in a case where the medium 3 is a solid.

The “ionic liquid” of the disclosure indicates a salt (ambient temperature molten salt) in a molten state even at an ambient temperature (for example, 25° C.), and is expressed as a general formula (1) below:

X⁺Y⁻ (1)

In the general formula (1), X⁺ is a cation selected from among imidazolium ion, pyridinium ion, phosphonium ion, aliphatic quaternary ammonium ion, pyrrolidinium, and sulfonium. Among these, it is particularly preferable that aliphatic quaternary ammonium ion is used as a cation since aliphatic quaternary ammonium ion is excellently stable thermally and in the air.

In the general formula (1), Y⁻ is an anion selected from among tetrafluoroboric acid ion, hexafluorophosphoric acid ion, bis(trifluoromethylsulfonyl)imide acid ion, perchloric acid ion, tris(trifluoromethylsulfonyl) carbon acid ion, trifluoromethanesulfonic acid ion, trifluoroacetic acid ion, carbonic acid ion, and halogen ion. Among these, it is particularly preferable that bis(trifluoromethylsulfonyl)imide acid ion is used as an anion since bis(trifluoromethylsulfonyl)imide acid ion is excellently stable thermally and in the air.

As an ionic liquid, it is possible to use an ionic liquid having a polymerizable functional group or an ionic liquid not having a polymerizable functional group. For example, 2-(methacryloyloxy)-ethyltrimethylammonium bis(trifluoromethanesulfonyl)imide (abbreviated as “MOE-200T”, hereinafter), 1-(3-acryloyloxy-propyl)-3-methylimidazolium bis(trifluoromethanesulfonyl)imide, and the like may be used as an ionic liquid having a polymerizable functional group. For example, N,N,N-trimethyl-N-propylammonium bis(trifluoromethanesulfonyl)imide, N,N-dimethyl-N-methyl-2-(2-methoxyethyl) ammonium bis(trifluoromethanesulfonyl)imide (abbreviated as “DEME-TFSI”, hereinafter), and the like may be used as an ionic liquid not having a polymerizable functional group.

The resin that includes the constitutional unit derived from the ionic liquid having the polymerizable functional group may be formed, for example, by curing the ionic liquid with heat or light by using a cross-linking agent.

In a case where the medium 3 is the ionic liquid or the resin including the constitutional unit derived from the ionic liquid, there is an advantage that the semiconductor nanoparticle phosphor 2 dispersed in the medium 3 in this manner is able to be dispersed appropriately in the medium 3 by the electrostatic effect of a positive charge 6 and a negative charge 7 derived from the ionic liquid in the medium 3. Since the organic modifying group 8 on the surface of the semiconductor nanoparticle phosphor 2 is stabilized by the electrostatic effect derived from the ionic liquid in the medium 3 and occurrence of the dangling bond due to separation from the surface of the semiconductor nanoparticle phosphor is suppressed, it is possible to suppress a decrease in quantum yield of the semiconductor nanoparticle phosphor. If the organic modifying group 8 includes a polar functional group or an ionic functional group and the polar functional group or the ionic functional group is present on the surface of the semiconductor nanoparticle phosphor, stability of the semiconductor nanoparticle phosphor 2 is further enhanced by an electrostatic interaction between the charge included in the functional groups and the positive charge 6 and the negative charge 7 derived from the ionic liquid. Moreover, since the medium 3 of the ionic liquid has substantially no volatility in a range of a temperature at which the medium 3 is normally used, there is an advantage that the medium 3 of the ionic liquid may be used at a high temperature at which a typical medium is volatilized.

In a case where other liquids than the ionic liquid are used as a liquid medium, it is preferable that a medium having a high boiling point (for example, boiling point of 200° C. or higher) such as octadecene described as an example above is used from the viewpoint that the medium is less likely to be volatilized under a normal use (such as LED) condition, reduction in a quantity of the medium due to volatilization of the medium or destruction of a capsule due to vapor pressure is less likely to be caused, and a light emitting element with high stability is obtained.

### Capsule-Shaped Material

The capsule-shaped material 4 of the examples illustrated in FIG. 1 and FIG. 2 is a hollow spherical material having a plurality of concave portions in the surface thereof. The shape of the capsule-shaped material of the disclosure is not particularly limited as long as the capsule-shaped material is a hollow material which has the concave portion in the surface and in which the medium 3 with the semiconductor nanoparticle phosphor 2 being dispersed may be sealed in an internal space thereof. The shape of the capsule-shaped material may be a spherical shape (true sphere shape, oblate sphere shape, or prolate sphere shape), a hexahedral shape, or a tetrahedral shape, but it is preferable that the capsule-shaped material is a hollow spherical material as illustrated in the examples in FIG. 1 and FIG. 2, from the viewpoint of ease in control of shape and size.

In the nanoparticle phosphor element 1 of the disclosure, the medium 3 in which the semiconductor nanoparticle phosphor 2 is dispersed is sealed in the capsule-shaped material 4, thereby, it is possible to suppress agglomeration of the semiconductor nanoparticle phosphor, and it is possible to suppress degradation of the semiconductor nanoparticle phosphor due to the agglomeration. Moreover, penetration of oxygen or moisture into the medium 3 may be suppressed, and the degradation of the semiconductor nanoparticle phosphor 2 due to oxygen or moisture may be suppressed.

In the nanoparticle phosphor element 1 of the disclosure, the capsule-shaped material 4 having a plurality of concave portions in the surface is used, and therefore there is an advantage that contact between the capsule-shaped material 4 and a sealing material 13 is appropriate (contact area is large) when the light emitting element 11 of the disclosure is provided by sealing the nanoparticle phosphor element 1 with the sealing material 13, as illustrated in FIG. 1 and FIG. 2. Accordingly, since the heat easily escapes to the sealing material 13 from the nanoparticle phosphor element 1, the quantity of the heat accumulated in the nanoparticle phosphor element 1 may be reduced, and the degradation of the semiconductor nanoparticle phosphor 2 due to the heat and the decrease in the efficiency may be suppressed. That is, as schematically illustrated in FIG. 2, in the light emitting element 11, excitation light L1 from a light source 12 enters the semiconductor nanoparticle phosphor 2, thereby, fluorescence L2 is generated. With the fluorescence L2, heat T is generated from the semiconductor nanoparticle phosphor 2. In the disclosure, the heat T escapes to the sealing material 13 from the nanoparticle phosphor element 1 at emission of light as described above, and it is possible to suppress a decrease in efficiency of the semiconductor nanoparticle phosphor 2 due to the heat.

The size of the capsule-shaped material 4 is not particularly limited. For example, in a case where the capsule-shaped material 4 is the hollow spherical material as illustrated in FIG. 1 and FIG. 2, a diameter thereof (diameter of a portion other than the concave portion) is preferably in a range of about 50 nm to about 1 mm, and more preferably in a range of about 100 nm to about 100 μm. In a case where the diameter of the capsule-shaped material 4 is less than about 100 nm, a loss due to scattering of excitation light tends to be large since a surface area/volume ratio per particle becomes large. In a case where the diameter of the capsule-shaped material 4 exceeds about 1 mm, it tends to be difficult to disperse the capsule-shaped material 4 in the sealing material described later in a process similar to the process for a phosphor of the related art.

The thickness of the capsule-shaped material 4 (thickness of a portion other than the concave portion) is, for example, preferably about 0.5 nm to about 0.5 mm, and more preferably about 10 nm to about 100 μm. In a case where the thickness of the capsule-shaped material 4 is less than about 0.5 nm, there is a tendency that the medium 3 is not sufficiently protected. In a case where the thickness of the capsule-shaped material 4 exceeds about 0.5 mm, the loss due to scattering of excitation light tends to be large.

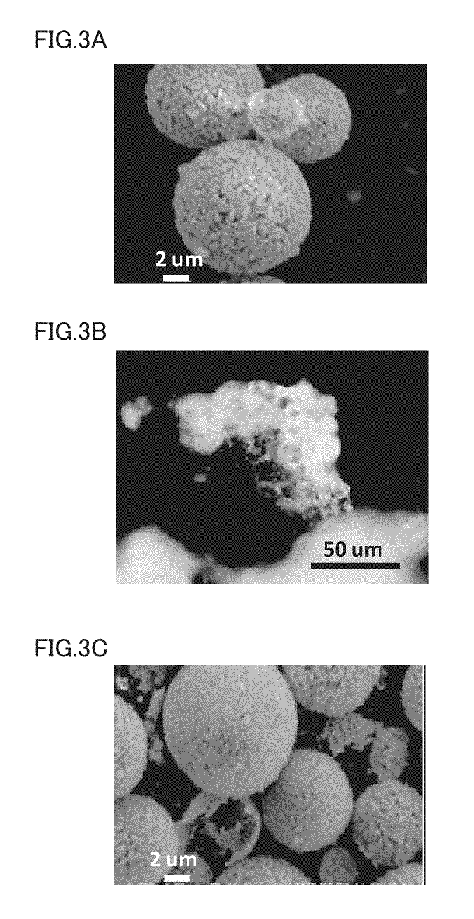

FIG. 3A is a scanning electron microscope (SEM) photograph (5000 magnification) of the nanoparticle phosphor element 1 (Example 1 described later) of the disclosure, FIG. 3B is a fluorescence microscopic image photograph (1000 magnification) of the nanoparticle phosphor element 1 (Example 1 described later) of the disclosure, and FIG. 3C is a scanning electron microscope (SEM) photograph (5000 magnification) of a nanoparticle phosphor element 21 (Example 2 described later) of the disclosure. It is possible to confirm the shape, the size, the thickness, the concave portion, and the like of the capsule-shaped material 4 in the nanoparticle phosphor element of the disclosure by using a scanning electron microscope, a fluorescence microscope, a transmission electron microscope, or the like. FIG. 3A illustrates a case where the capsule-shaped material 4 is formed of two layers (has a coating layer 5), and FIG. 3C illustrates a case where the capsule-shaped material 4 is formed of one layer. The capsule-shaped material 4 may have the coating layer 5 on the outside thereof as long as it is possible to have the plurality of concave portions in the surface as in FIG. 3A. Referring to FIG. 3B, it is possible to confirm emission of green fluorescence from the semiconductor nanoparticle phosphor in a fluorescence microscopic image at the time of 405 nm radiation.

The capsule-shaped material 4 (including the coating layer 5) is not particularly limited as long as it is a material that shields oxygen and moisture, and an inorganic material, a polymer material, or the like may be used. In a case where the capsule-shaped material is formed of at least two layers, the number of layers is not particularly limited as long as it is two or more, and a material of each layer is not particularly limited as long as it has oxygen and moisture shieldability. The materials of the respective layers may be all the same, may be all different, or only a portion thereof may be the same.

The inorganic material is excellent in oxygen and moisture shieldability. For example, silica, a metal oxide, a metal nitride, or the like may be used as an inorganic material.

Since a polymer material has flexibility, if the polymer material is used as a material of the capsule-shaped material 4, the nanoparticle phosphor element 1 is improved in shock resistance. Furthermore, since the polymer material may be formed under a condition which is moderate in comparison with that of the inorganic material, it is possible to suppress processing damages to the medium 3 and the semiconductor nanoparticle phosphor 2. Polyamide imide, acrylate polymer, epoxide, polyamide, polyimide, polyester, polycarbonate, polythioether, polyacrylonitrile, polydiene, polystyrene polybutadiene copolymer, parylene, silica-acrylate hybrid, polyether ether ketone, polyvinylidene fluoride, polyvinylidene chloride, polydivinylbenzene, polyethylene, polypropylene, polyethylene terephthalate, polyisobutylene, polyisoprene, cellulose derivatives, polytetrafluoroethylene, or the like may be used as a polymer material. In a case where the capsule-shaped material 4 is formed of two layers, a fluorine-based polymer (for example, Cytop (manufactured by Asahi Glass Co., Ltd.)) may be appropriately used for the coating layer 5 serving as the outside layer.

The capsule-shaped material 4 illustrated in FIG. 1 and FIG. 2 has two types of concave portions of the concave portion 4a which communicates with up to the internal space of the capsule-shaped material 4 and the concave portion 4b which does not communicate with the internal space. The shape of an opening of the concave portion is not particularly limited and may be a circular shape or an elliptical shape. From the viewpoint of exhibiting excellent heat dissipation properties by the appropriate contact with the sealing material 13 described above, it is preferable that a size of the opening of the concave portion (diameter in a case where the opening shape of the concave portion is the circular shape) is in a range of about 20 nm to about 10 μm, or in a range of about 100 nm to about 10 μm.

In the concave portion 4a, it is preferable that a diameter of a portion communicating with the internal space is in the range of about 20 nm to about 10 μm, or in the range of about 100 nm to about 10 μm. If the diameter of the portion communicating with the internal space in the concave portion 4a is about 10 μm or less, it is possible to suppress or prevent the medium 3 from flowing to the outside of the capsule-shaped material 4 even in a case where the liquid medium 3 is sealed inside the capsule-shaped material 4. Moreover, with the diameter of the portion communicating with the internal space in the concave portion 4a being in the range described above, the medium 3 in which the semiconductor nanoparticle phosphor 2 is dispersed may be efficiently introduced into the capsule-shaped material 4. This is because the semiconductor nanoparticle phosphor is able to easily pass through the portion communicating with the internal space in the concave portion 4a since the diameter of the portion communicating with the internal space in the concave portion 4a is larger than any semiconductor nanoparticle phosphor having the particle size of about 1 nm to about 20 nm preferable as a semiconductor nanoparticle phosphor if the diameter of the portion communicating with the internal space in the concave portion 4a is about 20 nm or more. The portion communicating with the internal space in the concave portion 4a is able to be sealed, after the medium 3 in which the semiconductor nanoparticle phosphor 2 is dispersed is sealed inside the capsule-shaped material 4 (for example, by the coating layer 5 illustrated in FIG. 1 and FIG. 2).

A depth of the concave portion 4b which does not communicate with the internal space is not particularly limited, but it is preferable that the depth thereof is in a range of about 1/100 to about ½ of the thickness of the capsule-shaped material 4, from the viewpoint of exhibiting excellent heat dissipation properties by the appropriate contact with the sealing material 13 described above.

It is preferable that a pitch between the concave portions (straight-line distance between the concave portions) is in a range of about 20 nm to about 100 μm, or more preferably in a range of about 20 nm to about 10 μm. In a case where the pitch is less than about 20 nm, the ratio of the capsule-shaped material to the opening diameter becomes small, and the protection of the medium 3 tends to be not sufficient. In a case where the pitch exceeds about 100 μm, there is a tendency that the ratio of the concave portion to the whole surface is small, and excellent heat dissipation properties are not able to be exhibited by the appropriate contact with the sealing material 13.

### Method for Manufacturing Nanoparticle Phosphor Element

The nanoparticle phosphor element may be manufactured by sealing the medium 3 in which the semiconductor nanoparticle phosphor 2 is dispersed in the capsule-shaped material 4 by using an existing capsule manufacturing method. A specific example of a manufacturing method will be illustrated below.

### Manufacturing of Semiconductor Nanoparticle Phosphor

A method for manufacturing the semiconductor nanoparticle phosphor 2 is not particularly limited, and may be any manufacturing method. It is preferable to use a chemical synthesis method as a method for manufacturing the semiconductor nanoparticle phosphor 2 from the viewpoint of simplicity of the method and a low cost. In the chemical synthesis method, an intended product is obtained by causing, after a plurality of starting materials including constituent elements of the product are dispersed in a medium, the materials to react. For example, a sol gel method (colloid method), a hot soap method, an inverted micelle method, a solvothermal method, a molecular precursor method, a hydrothermal synthesis method, a flux method, or the like may be used as such a chemical synthesis method. It is preferable to use the hot soap method from the viewpoint of appropriately manufacturing the nanoparticle core formed of compound semiconductor materials. Hereinafter, an example of the method for manufacturing the semiconductor nanoparticle phosphor 2 having a core-shell structure by the hot soap method will be illustrated.

First, the nanoparticle core is synthesized in liquid phase. For example, in a case where the nanoparticle core formed of InN is manufactured, a flask or the like is filled with 1-octadecene (synthesizing solvent), and tris(dimethylamino) indium and hexadecanethiol (HDT) are mixed together. After a mixture liquid thereof is sufficiently agitated, the mixture liquid is caused to react at a temperature of 180° C. to 500° C. Thereby, the nanoparticle core formed of InN is obtained, and HDT is bonded to the external surface of the obtained nanoparticle core. HDT may be added after the shell layer is grown.

It is preferable that the synthesizing solvent used in the hot soap method is a compound solution formed of a carbon atom and a hydrogen atom (referred to as a “hydrocarbon-based solvent”, hereinafter). Thereby, oxidization of the nanoparticle core is prevented since contamination of the synthesizing solvent due to moisture or oxygen is prevented. It is preferable that the hydrocarbon-based solvent is n-pentane, n-hexane, n-heptane, n-octane, cyclopentane, cyclohexane, cycloheptane, benzene, toluene, o-xylene, m-xylene, p-xylene, or the like, for example.

In the hot soap method, theoretically, the particle size of the nanoparticle core becomes large as the reaction time is long. Accordingly, the size of the nanoparticle core is controlled to be a desired size by performing a liquid phase synthesis while monitoring the particle size with photoluminescence, light absorption, or dynamic light scattering.

Next, a reaction reagent being a source material of the shell layer is added to the solution including the nanoparticle core, and a pyrogenetic reaction thereof is performed. Thereby, a starting material of the semiconductor nanoparticle phosphor is obtained. In the starting material of the obtained semiconductor nanoparticle phosphor, the external surface of the nanoparticle core is covered with the shell layer, and HDT is bonded to the external surface of the shell layer.

Subsequently, a modifying organic compound is added to the solution including the starting material of the semiconductor nanoparticle phosphor, and the added solution is caused to react at a temperature of room temperature to 300° C. Thereby, the bonding of the external surface of the shell layer to HDT is resolved, the modifying organic compound is bonded to the external surface of the shell layer, and the organic modifying group 8 is formed. In this manner, the semiconductor nanoparticle phosphor 2 is obtained.

At the time of manufacturing the nanoparticle core, the modifying organic compound may be added in place of HDT. In a case where the semiconductor nanoparticle phosphor 2 is obtained in this manner, the modifying organic compound may not necessarily be added after the shell layer is formed. Manufacturing of Capsule-Shaped Material 4

The obtained semiconductor nanoparticle phosphor 2 is dispersed in the medium 3. It is possible to use a value according to the use of the light emitting element for a volume ratio of the semiconductor nanoparticle phosphor 2 to the medium 3, and it is preferable that the volume ratio thereof is 0.000001 or more to 10 or less, for example.

Next, the capsule-shaped material 4 having a plurality of concave portions in the surface is prepared by the following method. An aqueous phase (W1 phase) of an aqueous solution of sodium silicate and an aqueous solution of polymethyl methacrylate, an n-hexane phase (O phase) of Tween 80 (polyoxyethylene sorbitan monooleate) and Span 80 (sorbitan monooleate), and an aqueous phase (W2 phase) of ammonium hydrogencarbonate are prepared. Next, after the W1 phase is added to the O phase, the added material is emulsified at a rotation speed of 8000 rpm with a homogenizer, and a W1/O phase is obtained. The W1/O phase is immediately added to the W2 phase, and is agitated for 2 hours at a temperature of 35° C. with a magnetic stirrer. Thereafter, a washing process is performed by repeating an operation of adding water or ethanol to the solution, performing centrifugation, and removing a supernatant. Thereafter, filtration is performed, and a precipitate is obtained. Thereafter, the precipitate is dried for 12 hours at a temperature of 100° C., and subsequently is baked for 5 hours at a temperature of 700° C., and a hollow silica capsule of an average particle size of approximately 10 μm having pores is obtained. It is also possible to manufacture the nanoparticle phosphor element by introducing the medium in which the semiconductor nanoparticle phosphor 2 is dispersed into the manufactured capsule-shaped material 4, and performing a process of curing the medium 3 (for example, the process of curing the ionic liquid is performed and the resin including the constitutional unit derived from the ionic liquid is formed). Thereby, at the time of introducing the medium into the capsule-shaped material 4, it is possible to appropriately manufacture the nanoparticle phosphor element without giving the processing damage to the semiconductor nanoparticle phosphor 2 or the medium 3 in which the semiconductor nanoparticle phosphor 2 is dispersed. In the process of curing the ionic liquid, it is possible to use a photo-curing method that performs the curing by exposing the ionic liquid to ultraviolet rays or a thermosetting method that performs the curing by applying heat to the ionic liquid.

### Light Emitting Element

As illustrated in FIG. 1 and FIG. 2, the light emitting element 11 includes the sealing material 13 and the nanoparticle phosphor element 1 of the disclosure described above that is dispersed in the sealing material 13. The light emitting element 11 of the examples illustrated in FIG. 1 and FIG. 2 includes the light source 12 that is integrally covered with the sealing material 13. In the light emitting element of the disclosure, a single type, or two or more types in combination may be used as a nanoparticle phosphor element.

The nanoparticle phosphor element 1 of the disclosure described above has excellent quantum efficiency. Since the surface is covered with a support, the nanoparticle phosphor elements 1 do not agglomerate together, and are able to be appropriately dispersed in the sealing material 13. Therefore, the light emitting element 11 including the nanoparticle phosphor element 1 has excellent light emission efficiency.

It is preferable to use a glass material or a macromolecular material as a sealing material 13. As a glass material, for example, tetramethoxysilane (TMOS), tetraethoxysilane (TEOS), tetrapropoxysilane, tetrabutoxysilane, or the like may be used. As a macromolecular material, for example, an acrylic resin such as polymethyl methacrylate (PMMA), an epoxy resin formed of bisphenol A and epichlorohydrin, or a resin including a constitutional unit which is derived from an ionic liquid formed of 2-(methacryloyloxy)-ethyltrimethylammonium bis(trifluoromethanesulfonyl)imide (MOE-200T), 1-(3-acryloyloxy-propyl)-3-methylimidazolium ethyltrimethylammonium bis(trifluoromethanesulfonyl)imide, or the like may be used.

It is possible to use the value according to the use of the light emitting element for a volume ratio of the nanoparticle phosphor element 1 to the sealing material 13, and it is preferable that the volume ratio thereof is 0.000001 or more to 10 or less, for example. In a case where a high transparency of the light emitting element is desired, it is preferable that the volume ratio of the nanoparticle phosphor element to the sealing material is 0.2 or less. If the volume ratio is 0.2 or less, it is possible to make the light emitting element having high transparency. In a case where a large quantity of light emitted by a light emitting device is desired, it is preferable that the volume ratio of the nanoparticle phosphor element to the sealing material is 0.00001 or more. If the volume ratio is 0.00001 or more, it is possible to make the light emitting device that emits a large quantity of light.

The sealing material 13 preferably includes 80% by volume or more, and more preferably 90% by volume or more of the glass material or the macromolecular material. If the sealing material 13 includes 80% by volume or more of the glass material or the macromolecular material, it is possible to make the light emitting element having high transparency or high light emission efficiency. If the sealing material 13 includes 90% by volume or more thereof, it is possible to make the light emitting element having transparency or light emission efficiency higher than in the case of including 80% by volume.

The combination of the type of the nanoparticle phosphor element with the type of the sealing material is not particularly limited, and can be selected in accordance with the use of the light emitting element.

### Method for Manufacturing Light Emitting Element

At the time of introducing the nanoparticle phosphor element 1 into the sealing material 13, the curing process is performed after the nanoparticle phosphor element 1 is dispersed in the sealing material 13.

In a case where a glass material is used as a sealing material 13, a solution obtained by mixing the glass material and the nanoparticle phosphor element 1 is agitated, thereby, the nanoparticle phosphor element 1 is dispersed in the glass material. Next, condensation reaction is performed onto the glass material, and the glass material is cured. In order to accelerate a process speed of the condensation reaction, heating may be carried out, or an acid or a base may be added to a system.

In a case where a macromolecular material is used as a sealing material 13, a solution obtained by mixing the macromolecular material and the nanoparticle phosphor element 1 is agitated, thereby, the nanoparticle phosphor element 1 is dispersed in the macromolecular material. Next, condensation reaction is performed onto the macromolecular material, and the macromolecular material is cured and resinified (solidified). In the curing method, it is possible to use the photo-curing method that performs the curing by exposing the material to ultraviolet rays or the thermosetting method that performs the curing by applying heat to the material.

### Embodiment 2

### Nanoparticle Phosphor Element

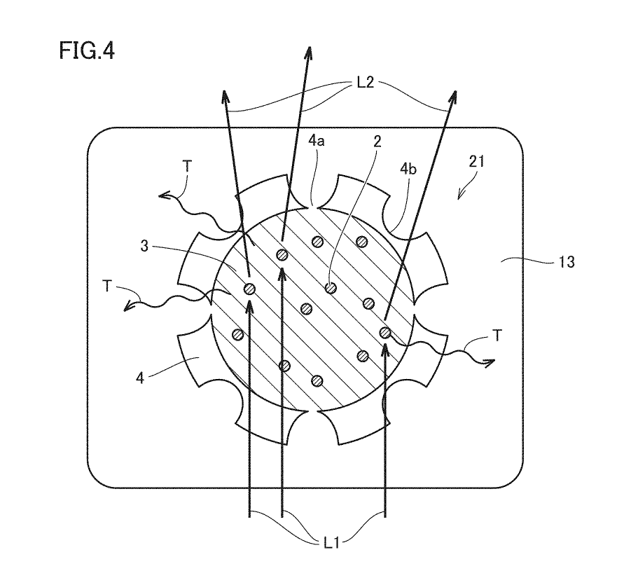

FIG. 4 is a diagram schematically illustrating a nanoparticle phosphor element 21 according to Embodiment 2. The nanoparticle phosphor element 21 of the example illustrated in FIG. 4 is different from the nanoparticle phosphor element 1 of the example illustrated in FIG. 1, only in a point that the capsule-shaped material 4 has only one layer, and does not have the coating layer. Even in the nanoparticle phosphor element 21 illustrated in FIG. 4, heat T which is generated at the time of emitting the fluorescence L2 from the semiconductor nanoparticle phosphor 2 by the entering of the excitation light L1 efficiently escapes while the contact of the capsule-shaped material 4 with the sealing material 13 is made appropriate by the plurality of concave portions in the surface, thereby, it is possible to suppress the degradation of the semiconductor nanoparticle phosphor due to the heat, as described above. Even in a case where the capsule-shaped material 4 does not have the coating layer as illustrated in FIG. 4, the medium 3 does not flow outside since the medium 3 is retained in the internal space of the capsule-shaped material 4 by a capillary phenomenon even in a case where the medium 3 is the liquid.

### Embodiment 3

### Light Emitting Element

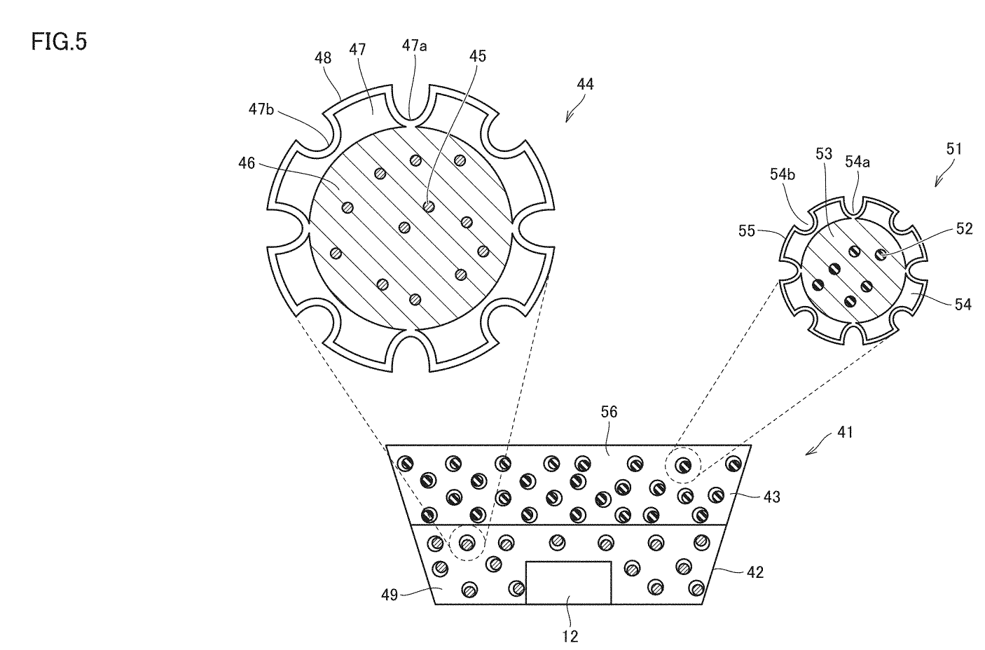

FIG. 5 is a diagram schematically illustrating a light emitting element 41 according to Embodiment 3. As illustrated in FIG. 5, the light emitting element 41 may have a multilayer structure including a first light emitting layer 42 in which a first nanoparticle phosphor element 44 is dispersed in a sealing material 49 and a second light emitting layer 43 in which a second nanoparticle phosphor element 51 is dispersed in a sealing material 56. In this case, for example, in the first nanoparticle phosphor element 44 included in the first light emitting layer 42, the medium 46 in which a semiconductor nanoparticle phosphor 45 emitting red light is dispersed is introduced into a capsule-shaped material 47 that has a plurality of concave portions 47a and 47b and a coating layer 48, and the first light emitting layer 42 functions as a red light emitting layer. In the second nanoparticle phosphor element 51 included in the second light emitting layer 43, the medium 53 in which a semiconductor nanoparticle phosphor 52 emitting green light is dispersed is introduced into a capsule-shaped material 54 that has a plurality of concave portions 54a and 54b and a coating layer 55, and the second light emitting layer 43 functions as a green light emitting layer. For example, an LED chip emitting blue light is used as a light source 12, and the first light emitting layer 42 functioning as a red light emitting layer, and the second light emitting layer 43 functioning as a green light emitting layer are stacked thereon in this order. Thereby, since reabsorption of energy to the first light emitting layer 42 from the second light emitting layer 43 is less likely to occur, light emission efficiency of the light emitting element 41 becomes appropriate.

### Method for Manufacturing Light Emitting Element

An example of the method for manufacturing the light emitting element which has a multilayer structure will be described below. In the following description, a case where the light emitting element has a two-layer structure will be described, but even in a case where the light emitting element has a structure of three layers or more, it is possible to manufacture the light emitting element by basically the similar method. First, two types of nanoparticle phosphor elements which have different sizes are prepared. A solution of the two types of nanoparticle phosphor elements is mixed into an acrylic resin material, and the mixture is dropped on the LED chip emitting blue light. Thereafter, a heating and curing process is performed. In the process of heating and curing, the nanoparticle phosphor element having a large particle size is settled after the lapse of a certain time, and a two-layer structure that is provided with a lower layer which mainly includes a nanoparticle phosphor element having a large particle size and an upper layer which mainly includes a nanoparticle phosphor element having a small particle size is formed as a light emitting element.

According to the manufacturing method described above, it is possible to simplify a manufacturing process since a complicated process such that the respective layers are individually formed is dispensable.

### Embodiment 4

Needless to say, the capsule-shaped material of the disclosure may have a structure that all the concave portions communicate with up to the internal space of the capsule-shaped material, that is, all the concave portions are communication holes. However, from the viewpoint of heat dissipation to the sealing material from the nanoparticle phosphor element described above, it is desirable that the capsule-shaped material is composed to have two types of concave portions of the concave portion 4a which communicates with up to the internal space of the capsule-shaped material 4 and the concave portion 4b which does not communicate with the internal space (not include the coating layer), as the example illustrated in FIG. 4. In other words, the more the area of the internal space side of the capsule-shaped material that is in contact with the medium in which the semiconductor nanoparticle is dispersed, the more the effect of the heat dissipation to the sealing material from the nanoparticle phosphor element. From the viewpoint of obtaining high heat dissipation effect, it is particularly preferable that the capsule-shaped material 4 is composed to have two types of concave portions of the concave portion 4a which communicates with up to the internal space of the capsule-shaped material 4 and the concave portion 4b which does not communicate with the internal space, and to close the concave portion communicating with the internal space by the coating layer, as the examples illustrated in FIG. 1 and FIG. 2.

### EXAMPLES

The disclosure will be more specifically described by examples. However, the disclosure is not limited by the examples. Hereinafter, “A/B” indicates that A is covered with B.

### Example 1

Example 1 is a case where the nanoparticle core is CdSe, the shell layer is ZnS, the organic modifying group is dimethylaminoethanethiol (DAET), the medium is N,N,N-trimethyl-N-propylammonium bis(trifluoromethanesulfonyl)imide and N,N-dimethyl-N-methyl-2-(2-methoxyethyl) ammonium bis(trifluoromethanesulfonyl)imide (DEME-TFSI), the capsule-shaped material is silica, and the coating layer is Cytop which is a fluorine-based polymer (manufactured by Asahi Glass Co., Ltd.) (semiconductor nanoparticle phosphor: CdSe/ZnS/DAET, and nanoparticle phosphor element: semiconductor nanoparticle phosphor/DEME-TFSI/silica/Cytop).

### Manufacturing of Nanoparticle Phosphor Element

First, an octadecene (ODE) solution of a semiconductor nanoparticle phosphor formed of nanoparticle core of CdSe, a shell layer of ZnS, and an organic modifying group of hexadecanethiol (HDT) was prepared. In the semiconductor nanoparticle phosphor, an organic modifying group substitution treatment was performed to substitute HDT with DAET, and the semiconductor nanoparticle phosphor was moved into a DEME-TFSI solvent.

Subsequently, a silica-made hollow spherical material (capsule-shaped material) of an average particle size of 10 μm having a plurality of concave portions in a surface was separately prepared based on a known literature of Takafumi Toyoda et al., “Fabrication Process of Silica Hard-shell Microcapsule (HSMC) Containing Phase-change Materials”, Chem. Lett. 2014, 43, 820-821. After a UV ozone treatment was performed onto the hollow spherical material made of silica, an APrS treatment was performed by causing gas phase reaction of aminopropyltrimethoxysilane (APrS) and nitrogen in N₂ for 3 hours at a temperature of 90° C., and a capsule-shaped material was manufactured. The capsule-shaped material onto which the APrS treatment was performed, and DEME-TFSI containing the semiconductor nanoparticle phosphor were mixed, and DEME-TFSI containing the semiconductor nanoparticle phosphor was introduced into the capsule-shaped material by being vacuumed. A portion communicating with the internal space of the concave portion 4a of the capsule-shaped material is closed by dropping a 6% Cytop solution on the capsule-shaped material, agitating, and drying the capsule-shaped material at a temperature of 80° C. Finally, Cytop was polymerized by applying heat for 1 hour at a temperature of 80° C. As described above, FIG. 3A is the SEM photograph of the nanoparticle phosphor element manufactured, and the capsule-shaped material 4 having the coating layer 5 was confirmed to have a plurality of concave portions in the surface.

### Manufacturing of Light Emitting Element

The nanoparticle phosphor element of Example 1 manufactured in the above manner was mixed into an acrylic resin, and the mixture was dropped on a blue light LED chip. Thereafter, the acrylic resin is cured and a LED light emitting element was manufactured. The LED light emitting element kept high efficiency for a long time by being observed for change over time in a lighting test, that is, had appropriate quantum efficiency and appropriate stability.

### Example 2

In the same manner as in Example 1 except that the capsule-shaped material 4 did not have the coating layer 5, a nanoparticle phosphor element and a light emitting element were manufactured (semiconductor nanoparticle phosphor: CdSe/ZnS/DAET, and nanoparticle phosphor element: semiconductor nanoparticle phosphor/DEME-TFSI/silica). As described above, FIG. 3C is the SEM photograph of the nanoparticle phosphor element manufactured, and the capsule-shaped material 4 was confirmed to have a plurality of concave portions in the surface. Similarly to the light emitting element of Example 1, the light emitting element manufactured in Example 2 also kept high efficiency for a long time by being observed for change over time in the lighting test, that is, had appropriate quantum efficiency and appropriate stability.

### Example 3

In the same manner as in Example 1 except that a treatment after manufacturing a hollow spherical material (capsule-shaped material) made of silica was performed by N-trimethoxysilylpropyl-N,N,N-trimethylammonium chloride (STMA) in place of APrS, and the coating layer was formed of silica, a nanoparticle phosphor element and a light emitting element were manufactured (semiconductor nanoparticle phosphor: CdSe/ZnS/DAET, and nanoparticle phosphor element: semiconductor nanoparticle phosphor/DEME-TFSI/silica/silica).

The STMA treatment on the capsule-shaped material was performed by mixing the capsule-shaped material with STMA in a 2-propanol solvent after performing the UV ozone treatment onto the capsule-shaped material, and causing the capsule-shaped material to react for 5 hours at a temperature of 80° C. The coating layer made of silica was formed by mixing the capsule-shaped material into which DEME-TFSI containing the semiconductor nanoparticle phosphor was introduced with an aqueous solution of ammonium hydrogencarbonate and an aqueous solution of sodium silicate, and causing the capsule-shaped material to react for 3 hours at a room temperature. In this manner, in the disclosure, it is possible to use not only a polymer but also an inorganic material such as silica for the coating layer. In that case, it is possible to expect a higher coating effect (lower gas permeability and lower moisture permeability) than that of a case where the coating layer is formed of the polymer. On the other hand, since the coating layer becomes a hard film, shock resistance is considered to be lower than that of a case where coating layer is formed of the polymer (since the coating layer is soft if being the polymer, it is possible to absorb a shock to some extent).

Similarly to the light emitting element of Example 1, the light emitting element manufactured in Example 3 also kept high efficiency for a long time by being observed for change over time in the lighting test, that is, had appropriate quantum efficiency and appropriate stability.

### Example 4

In the same manner as in Example 1 except that a resin including a constitutional unit derived from an ionic liquid having a polymerizable functional group (resin including a constitutional unit derived from MOE-200T) was used as a medium, a nanoparticle phosphor element and a light emitting element were manufactured (semiconductor nanoparticle phosphor: CdSe/ZnS/DAET, and nanoparticle phosphor element: semiconductor nanoparticle phosphor/MOE-200T/silica/Cytop).

First, a semiconductor nanoparticle phosphor was dispersed in MOE-200T of a solution state, and the material was dropped on a hollow spherical material (capsule-shaped material) made of silica onto which the APrS treatment was performed, and the capsule-shaped material into which a resin including a constitutional unit derived from MOE-200T was sealed was manufactured by being vacuumed. Thereafter, MOE-200T was polymerized by applying heat to the capsule-shaped material at a temperature of 80° C., and the resin including the constitutional unit derived from the ionic liquid is made.

Similarly to the light emitting element of Example 1, the light emitting element manufactured in Example 4 also kept high efficiency for a long time by being observed for change over time in the lighting test, that is, had appropriate quantum efficiency and appropriate stability. In this manner, it is possible to enhance the stability of the semiconductor nanoparticle phosphor by the electrostatic interaction even by using the resin that includes the constitutional unit derived from the ionic liquid having the polymerizable functional group as a solid medium, in the same manner as a case where the ionic liquid is used as a liquid medium. Moreover, the medium is solid, thereby, the medium does not leak out when the capsule-shaped material cracks as in the case where the medium is liquid, and it is possible to obtain the nanoparticle phosphor element which is excellent in shock resistance.

### Example 5

In the same manner as in Example 1 except that a capsule-shaped material was manufactured by using a polymer (polyamideimide), a nanoparticle phosphor element and a light emitting element were manufactured (semiconductor nanoparticle phosphor: CdSe/ZnS/DAET, and nanoparticle phosphor element: semiconductor nanoparticle phosphor/DEME-TFSI/polyamideimide/Cytop).

First, DEME-TFSI containing a semiconductor nanoparticle phosphor was mixed with a solution in which polyamideimide was dissolved, and subsequently was heated and agitated. Thereby, polyamideimide was formed in the vicinity of DEME-TFSI containing the semiconductor nanoparticle phosphor, and a capsule-shaped material was manufactured by using polyamideimide.

Similarly to the light emitting element of Example 1, the light emitting element manufactured in Example 5 also kept high efficiency for a long time by being observed for change over time in the lighting test, that is, had appropriate quantum efficiency and appropriate stability. As in Example 5, by manufacturing the capsule-shaped material by using the polymer, since it is possible to manufacture the capsule-shaped material under a condition which is moderate in comparison with that of the inorganic material such as silica, there is an advantage that the processing damage to the semiconductor nanoparticle phosphor which is dispersed in the medium is small. Since the capsule-shaped material manufactured by using the polymer is flexible in comparison with the capsule-shaped material manufactured by using the inorganic material such as silica, there is an advantage that the capsule-shaped material of the polymer is less likely to crack.

### Example 6

Example 6 is a case where carboxydecanethiol (CDT) is used as an organic modifying group, in place of DAET, in the semiconductor nanoparticle phosphor of Example 1 (semiconductor nanoparticle phosphor: CdSe/ZnS/CDT, and nanoparticle phosphor element: semiconductor nanoparticle phosphor/DEME-TFSI/silica/Cytop).

### Manufacturing of Nanoparticle Phosphor Element

An ODE solution of a semiconductor nanoparticle phosphor formed of nanoparticle core of CdSe, a shell layer of ZnS, and an organic modifying group of hexadecanethiol (HDT) was prepared. In the semiconductor nanoparticle phosphor, after the organic modifying group substitution treatment was performed to substitute HDT with CDT, the semiconductor nanoparticle phosphor was moved into a DEME-TFSI solvent. Subsequently, a nanoparticle phosphor element and a light emitting element were manufactured in the same manner as in Example 1.

Similarly to the light emitting element of Example 1, the light emitting element manufactured in Example 6 also kept high efficiency for a long time by being observed for change over time in the lighting test, that is, had appropriate quantum efficiency and appropriate stability. As in Example 6, it is possible to use other materials than an ionic organic modifying group for the organic modifying group of the semiconductor nanoparticle phosphor. In the semiconductor nanoparticle phosphor, synthesis conditions including the types thereof contribute to properties such as quantum efficiency, light emission peak wavelength, light emission line width, and the like. Since the number of ionic organic modifying groups is small, if the organic modifying group is limited to have ionic properties, degrees of freedom is small in design in the manufacturing of the semiconductor nanoparticle phosphor, and eventually in the manufacturing of the nanoparticle phosphor element. Therefore, the manufacturing of the semiconductor nanoparticle phosphor having desired properties is difficult. As illustrated in Example 6, in the disclosure, it is possible to use other organic modifying groups than the ionic organic modifying group, and it is possible to design the semiconductor nanoparticle phosphor and the nanoparticle phosphor element with high degrees of freedom so that the semiconductor nanoparticle phosphor having desired properties is easily manufactured.

### Example 7

Example 7 is a case where octadecene (ODE) is used as a medium, and the organic modifying group of the semiconductor nanoparticle phosphor is hexadecanethiol (HDT), in the nanoparticle phosphor element of Example 1 (semiconductor nanoparticle phosphor: CdSe/ZnS/HDT, and nanoparticle phosphor element: semiconductor nanoparticle phosphor/ODE/silica/Cytop).

Specifically, a nanoparticle phosphor element and a light emitting element were manufactured in the same manner as in Example 1 except that ODE containing CdSe/ZnS/HDT was sealed in a hollow spherical material (capsule-shaped material) made of silica without performing the organic modifying group substitution treatment or the like.

Similarly to the light emitting element of Example 1, the light emitting element manufactured in Example 7 also kept high efficiency for a long time by being observed for change over time in the lighting test, that is, had appropriate quantum efficiency and appropriate stability. As in Example 7, in the disclosure, it is possible to use other liquids than the ionic liquid as a liquid medium. In this case, it is preferable to use a medium having a high boiling point (for example, boiling point of 200° C. or higher) from the viewpoint of obtaining the light emitting element with high stability in which the medium is less likely to be volatilized under the normal use (such as LED) condition, and the reduction of the quantity of the medium due to volatilization of the medium or the destruction of the capsule due to the vapor pressure is less likely to be caused. In this manner, by selecting an appropriate combination of the medium and the organic modifying group, the semiconductor nanoparticle phosphor and the nanoparticle phosphor element are designed with high degrees of freedom so that the semiconductor nanoparticle phosphor having desired properties is easily manufactured.

### Example 8

A light emitting element including the first light emitting layer (semiconductor nanoparticle phosphor (red light emission)/DEME-TFSI/silica/Cytop/acrylic resin) and the second light emitting layer (semiconductor nanoparticle phosphor (green light emission)/DEME-TFSI/silica/Cytop/acrylic resin) as illustrated in FIG. 5 was manufactured. A nanoparticle phosphor element was manufactured in the same manner as in Example 1 (CdSe/ZnS/DAET/DEME-TFSI/silica/Cytop). The manufactured nanoparticle phosphor element had a light emission peak wavelength in a region of red light. Similarly, a nanoparticle phosphor element having a light emission peak wavelength in a region of green light was manufactured. The particle size was assumed to be the semiconductor nanoparticle phosphor of red light emission >the semiconductor nanoparticle phosphor of green light emission, and the nanoparticle phosphor element of red light emission >the nanoparticle phosphor element of green light emission.

A solution of the two types of nanoparticle phosphor elements was mixed in an acrylic resin material, and was dropped on the LED chip. Thereafter, the heating and curing process was performed. As a result, during the heating and curing process, the nanoparticle phosphor element of red light emission having a large particle size was settled after the lapse of a certain time, and a light emitting element of a two-layer structure which is provided with a first light emitting layer mainly including the nanoparticle phosphor element of red light emission and a second light emitting layer mainly including the nanoparticle phosphor element of green light emission was manufactured. In this manner, in a case where the nanoparticle phosphor elements having the particle sizes which are different from each other are used, it is possible to manufacture the light emitting element having a two-layer structure as illustrated in FIG. 5 by a simple process of only mixing the both and allowing the mixture to stand, and a complicated process such as independently forming the green light emitting layer and the red light emitting layer is dispensable. As described above, in such a light emitting element, since the reabsorption of the energy to the first light emitting layer being the red light emitting layer from the second light emitting layer being the green light emitting layer is less likely to occur, the light emission efficiency thereof becomes appropriate.

The present disclosure contains subject matter related to that disclosed in Japanese Priority Patent Application JP 2016-113518 filed in the Japan Patent Office on Jun. 7, 2016, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A nanoparticle phosphor element comprising:
a capsule-shaped material having a plurality of concave portions in a surface;
a medium that is sealed in the capsule-shaped material; and
a semiconductor nanoparticle phosphor that is dispersed in the medium.

2. The nanoparticle phosphor element according to claim 1, wherein
the capsule-shaped material includes at least two layers.

3. The nanoparticle phosphor element according to claim 1, wherein
the medium is a liquid.

4. The nanoparticle phosphor element according to claim 2, wherein
the medium is a liquid.

5. The nanoparticle phosphor element according to claim 3, wherein
the medium is an ionic liquid.

6. The nanoparticle phosphor element according to claim 4, wherein
the medium is an ionic liquid.

7. The nanoparticle phosphor element according to claim 1, wherein
the medium is a solid.

8. The nanoparticle phosphor element according to claim 2, wherein
the medium is a solid.

9. The nanoparticle phosphor element according to claim 7, wherein
the medium is a resin that includes a constitutional unit derived from an ionic liquid having a polymerizable functional group.

10. The nanoparticle phosphor element according to claim 8, wherein
the medium is a resin that includes a constitutional unit derived from an ionic liquid having a polymerizable functional group.

11. A light emitting element comprising:
a sealing material; and
the nanoparticle phosphor element according to claim 1 that is dispersed in the sealing material.

12. A light emitting element comprising:
a sealing material; and
the nanoparticle phosphor element according to claim 2 that is dispersed in the sealing material.

13. A light emitting element comprising:
a sealing material; and
the nanoparticle phosphor element according to claim 3 that is dispersed in the sealing material.

14. A light emitting element comprising:
a sealing material; and
the nanoparticle phosphor element according to claim 4 that is dispersed in the sealing material.

15. A light emitting element comprising:
a sealing material; and
the nanoparticle phosphor element according to claim 5 that is dispersed in the sealing material.

16. A light emitting element comprising:
a sealing material; and
the nanoparticle phosphor element according to claim 6 that is dispersed in the sealing material.

17. A light emitting element comprising:
a sealing material; and
the nanoparticle phosphor element according to claim 7 that is dispersed in the sealing material.

18. A light emitting element comprising:
a sealing material; and
the nanoparticle phosphor element according to claim 8 that is dispersed in the sealing material.

19. A light emitting element comprising:
a sealing material; and
the nanoparticle phosphor element according to claim 9 that is dispersed in the sealing material.

20. A light emitting element comprising:
a sealing material; and
the nanoparticle phosphor element according to claim 10 that is dispersed in the sealing material.
